(19) United States
(12) Patent Application Publication
(10) Pub. No.: US 2008/0035913 A1
(43) Pub. Date: Feb. 14, 2008

(54) MOLECULAR RESONANT TUNNELING DIODE

(75) Inventors: Roger Lake, Riverside, CA (US); Khairul Alam, Riverside, CA (US); Nicholas A. Burque, Riverside, CA (US); Rajeev Pandey, Riverside, CA (US)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: The Regents of the University of California, Oakland, CA (US)

(21) Appl. No.: 11/464,455

(22) Filed: Aug. 14, 2006

(51) Int. Cl. H01L 29/08

(52) U.S. Cl. 257/40

(57) ABSTRACT

Molecular resonant tunneling diode (RTD) devices that include a molecular linker or bridge between two carbon nanotube (CNT) leads. Such devices include organic material self-assembled between two leads to yield RTD device behavior without the use of metallization of the organic material. Such devices alleviate the aforementioned problems associated with similar devices. Semiconducting carbon nanotubes (CNTs) may be used, and electrical functionality of the device is provided, not by intrinsic bistable properties of the bridge molecule, but by the crossing of resonant levels with the band edges of the leads.

### STATEMENT AS TO RIGHTS TO INVENTIONS MADE UNDER FEDERALLY SPONSORED RESEARCH OR DEVELOPMENT

This invention was made with Government support under Grant No. DMR-0103248 awarded by the NSF and grants DMEA90-02-2-0216 & H94003-04-2-0404 awarded by the Department of Defense. The Government has certain rights in this invention.

### BACKGROUND OF THE INVENTION

The present invention relates generally to diodes, and more particularly to molecular resonant tunneling diodes (RTDs).

Nanoelectronics has allowed the semiconductor industry to process millions of transistors and diodes into integrated circuits. To continue the trend of down-scaling electronic devices, research interests have focused on alternative materials for better performance, power efficiency and ease of assembly at the nanometer scale. More notably, biological structures combined with well established semiconducting materials have been used for built-in naturally occurring functionality. State-of-the-art methods have brought together disparate materials such as metals, semiconductor nanocrystals, DNA, Peptide Nucleic Acid (PNA), proteins, peptides, and carbon nanotubes (CNTs) (see, e.g., references 1-3 below). The direct assembly of these inorganic and organic materials is expected to provide better performance, lower costs and improve power efficiency in the next-generation of nanoscale field-effect transistors (FETs) and resonant tunneling diodes (RTDs). Examples of direct self-assembly include complementary base pairing of DNA bringing together inorganic materials, most notably CNTs (see, e.g., references 4-6 below). Assembling CNTFETs without direct patterning is of high research interest since no known method exists to construct complex circuits from CNT-based devices (see, e.g., references 7-10 below).

Self-assembled CNTs, using biologically-based mechanisms, may provide a process to construct complex circuits out of uniquely engineered CNT devices. An example of a bio-assembled device was developed by Keren et al. who created a CNT FET using self-assembly (see, e.g., reference 6 below). However, Keren et al. used metallization of the DNA between inorganic gold contacts thereby allowing ohmic conductivity of the DNA to drive the device. Using metallized DNA, and/or using metal interconnects with CNT's compromises the biological functionality of the DNA during metallization and creates brittle DNA segments that are unfeasible for use in complex circuit geometries (see, e.g., references 11-15 below). Other studies have found that molecular devices using benzene dithiol (BDT) type molecules bonded to silicon and driven by a STM potential (metal contact) exhibit negative differential resistance (NDR). (see, e.g., references 16-21 below). However the simplicity of such molecular devices lends itself to very few practical applications.

Therefore it is desirable to provide molecular devices that overcome the above and other problems.

### BRIEF SUMMARY OF THE INVENTION

The present invention provides molecular resonant tunneling diode (RTD) devices that include a molecular linker or bridge between two CNT leads.

Devices according to one embodiment of the invention include organic material self-assembled between two CNT (one or both being semiconducting CNTs) leads to yield RTD device behavior without the use of metallization contacts or metallization of organic material. Such devices alleviate the aforementioned problems associated with similar devices. In certain aspects, semiconducting carbon nanotubes (CNTs) are used, and electrical functionality of the device is provided, not by intrinsic bistable properties of the bridge molecule, but by the crossing of resonant levels with the band edges of the leads.

According to one aspect of the present invention, a molecular resonant tunneling diode (RTD) is provided that typically includes a first semiconducting carbon nanotube (CNT) lead, a second CNT lead, and organic material coupling the first and second CNT leads wherein the organic material is chemically bonded to a proximal end of the first CNT lead and to a proximal end of the second CNT lead. In certain aspects, the second metallic lead is semiconducting or it is metallic.

Reference to the remaining portions of the specification, including the drawings and claims, will realize other features and advantages of the present invention. Further features and advantages of the present invention, as well as the structure and operation of various embodiments of the present invention, are described in detail below with respect to the accompanying drawings. In the drawings, like reference numbers indicate identical or functionally similar elements.

### BRIEF DESCRIPTION OF THE DRAWINGS

FIG. 1 illustrates a device according to one embodiment of the invention that includes organic material self-assembled between two semiconductor leads to yield RTD device behavior. The organic material shown in FIG. 1 includes a DNA segment (GCCG) connected to CNTs via amide linkers.

FIG. 2 illustrates another embodiment of an RTD device 10 where the molecular portion 13 includes a psuedopeptide structure.

FIG. 3 shows a plot of the transmission of a CNT-pseudopeptide-CNT structure (solid line) a plot of a bare (10,0) zigzag CNT structure (dashed line).

FIG. 4 illustrates a surface contour plot corresponding to the spectral function at point A of FIG. 3.

FIG. 5 illustrates a surface contour plot corresponding to the spectral function at point B of FIG. 3.

FIG. 6 shows a plot of the calculated current voltage (I-V) response of the CNT-pseudopeptide-CNT structure shown in FIG. 2.

### DETAILED DESCRIPTION OF THE INVENTION

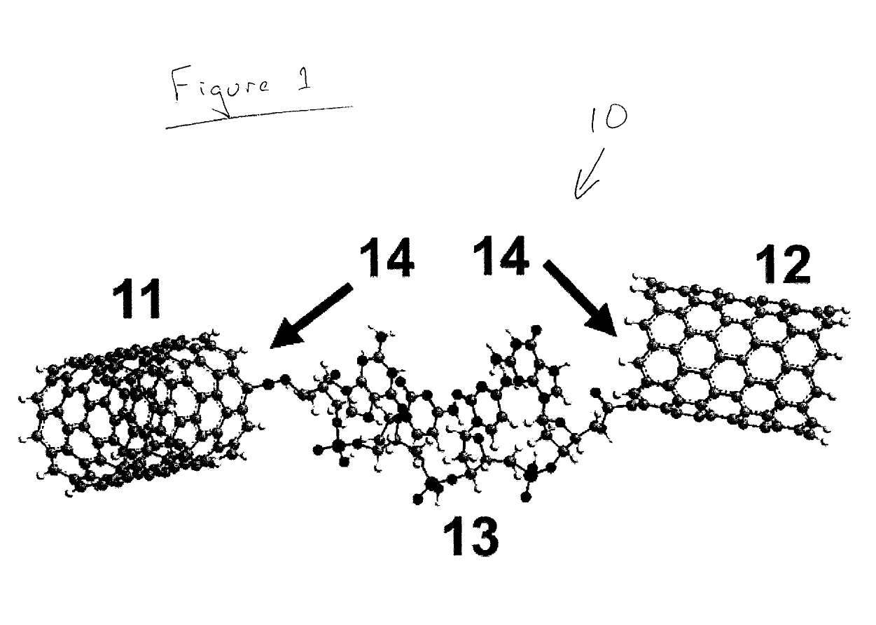

The present invention provides molecular resonant tunneling diode (RTD) devices including a molecular bridge between two semi-conducting leads. FIG. 1 illustrates a molecular-based resonant tunneling diode (RTD) 10 according to one embodiment. The RTD 10 includes two semi-conductor leads, the source 11 and drain 12, bound together by organic biological material 13. The organic material 13 is driven by the semi-conducting drain 12 and source 11. The semiconducting leads 11,12 on both sides of the organic material 13 provide a highly controlled source and drain interface which enhances the resonant-tunneling behavior of the organic material 13. Where prior methods and devices used metallization of the organic self-assembled material to improve conductivity and provide an ohmic interconnect, the present invention takes advantage of the inherent tunneling aspect of the organic material which is enhanced by the semiconducting source and drain terminals.

The molecular portion of the RTD 10, the organic material 13, provides distinctions among the semi-conducting leads 11,12 for complex integrated circuit design and acts as the primary source of electrical activity for the molecular RTD device. For example, in one aspect, as shown in FIG. 1, organic material 13 includes a DNA segment (GCCG) that is used as the driving mechanism of the RTD and is not exclusively used for self-assembly of two semiconducting CNTs as was done in prior methods. In certain aspects, the organic component 13 includes a predetermined biological or organic chemical group and is chemically bonded to the inorganic semi-conducting leads 11,12. The organic material 13, in certain aspects, contains biological built-in functionality allowing self-assembly of the inorganic leads to occur without direct human intervention.

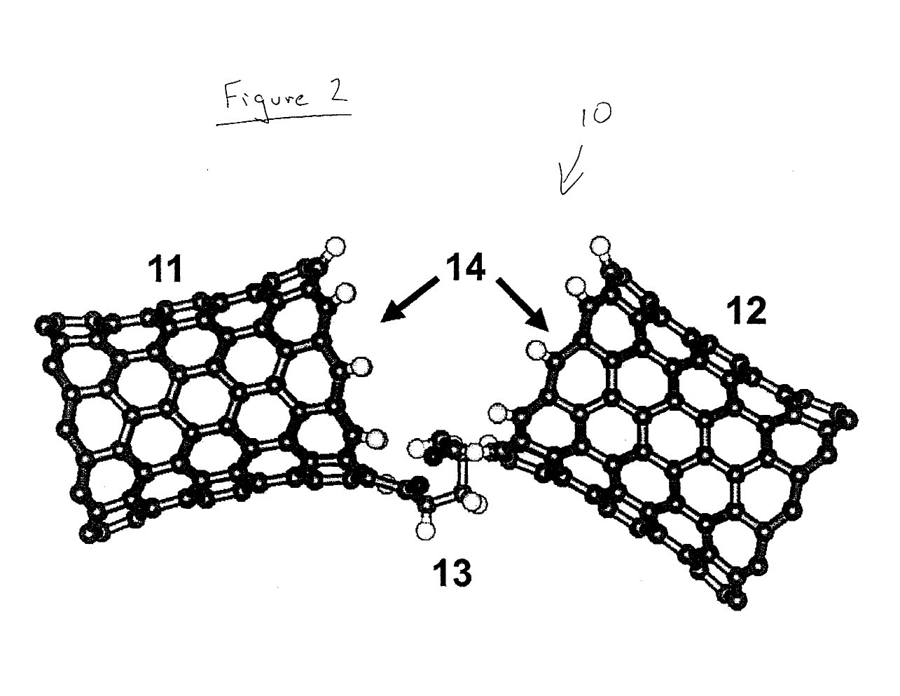

FIG. 2 illustrates another embodiment of an RTD device 10 where the molecular portion 13 includes a psuedopeptide structure. In one aspect, RTD device 10 includes two semiconducting (10,0) zigzag carbon nanotubes 11,12 attached to a pseudopeptide molecule 13. It should be appreciated that other CNT configurations and chiralities may be used. For example, other chiralities such as (n,m), where (n-m) is not a multiple of three may be used. In one aspect, the CNT ends 14 facing the pseudo-peptide molecule 13 are passivated to reduce tunneling states within the band-gap. The molecular structure closely resembles the pseudopeptide backbone of PNA which is an example of a bio-assembled structure.

The RTD molecule devices illustrated in FIGS. 1 and 2 have potential applications in logic circuits, low-power memory circuits and high-speed communication electronics (see, e.g., references 22-25 below). RTDs have been found to lower total power consumption and improve performance in complex microelectronics.

In certain aspects, a molecular RTD is constructed using bottom-up self-assembled techniques to construct complex circuit geometries at the nanometer scale. One distinguishing feature of the present invention over prior devices is the semiconducting source 11 or drain 12, which provide a bandgap energy on one side or the other side of the molecular structure 13. The source/drain characteristic is unique to the devices of the present invention since carrier action is dictated by a band-gap when a voltage potential is applied to the source/drain terminals causing electrons or holes to be injected into the molecule from the semiconducting source. The drain electrode (CNT) can be metallic.

In certain aspects, biological molecular linking structures 13 include materials such as peptides, glutamate, DNA, PNA, which provide the molecular component of the RTD for self-assembly purposes. Other molecular linking structure materials might include conducting organic polymers like disubstituted oligomeric olefines, disubstituted oligomeric alkanes, polyaromatics, 2,5-disubstituted oligothiophenes and dimercaptodiphenylacetylene etc. as shown in Table 1.

In certain aspects, covalent or self-assembled functionalization of the CNT ends with molecular material is done by oxidizing the CNTs, e.g., with nitric acid, to remove the caps and terminate the CNT with a carboxylic group (—COOH). The end functionalization is then completed by EDC coupling reaction which results in linking a CNT with the molecular material via an amide group (—CONH—). Some other linkers that could be used based on the ease of their reactivity to oxidized CNTs as well as their specific electronic properties include the ester group (—COO—), the thioester group (—COS—) and the imino group (—HC═N—) as shown in Table 1. This table also lists the compatibility of these linkers with different molecular groups (R).

TABLE 1
List of molecules and compatible linkers

| | | Linker (L) | | | |
|---|---|---|---|---|---|
| No | Molecule (R) | Amide | Thioester | Ester | Imino |
| I | 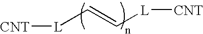 | 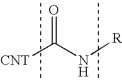 | 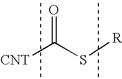 | 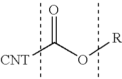 | 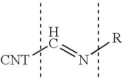 |
| | disubstituted oligomeric olefine | | | | |
| II | 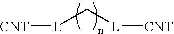 | 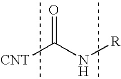 | 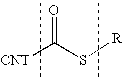 | 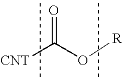 | 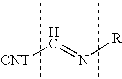 |
| | disubstituted oligomeric alkane | | | | |
| III | 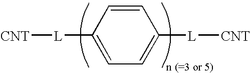 | 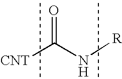 | 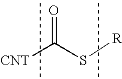 | 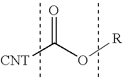 | 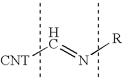 |
| | polyaromatic | | | | |
| IV | 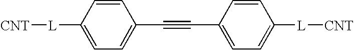 | 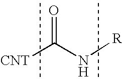 | 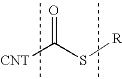 | — | 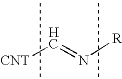 |
| | Dimercaptodiphenylacetylene | | | | |
| V | 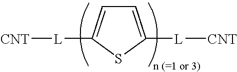 | 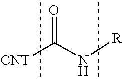 | 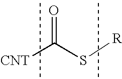 | 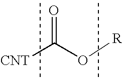 | 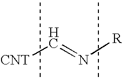 |
| | 2,5-disubstituted oligothiophene | | | | |

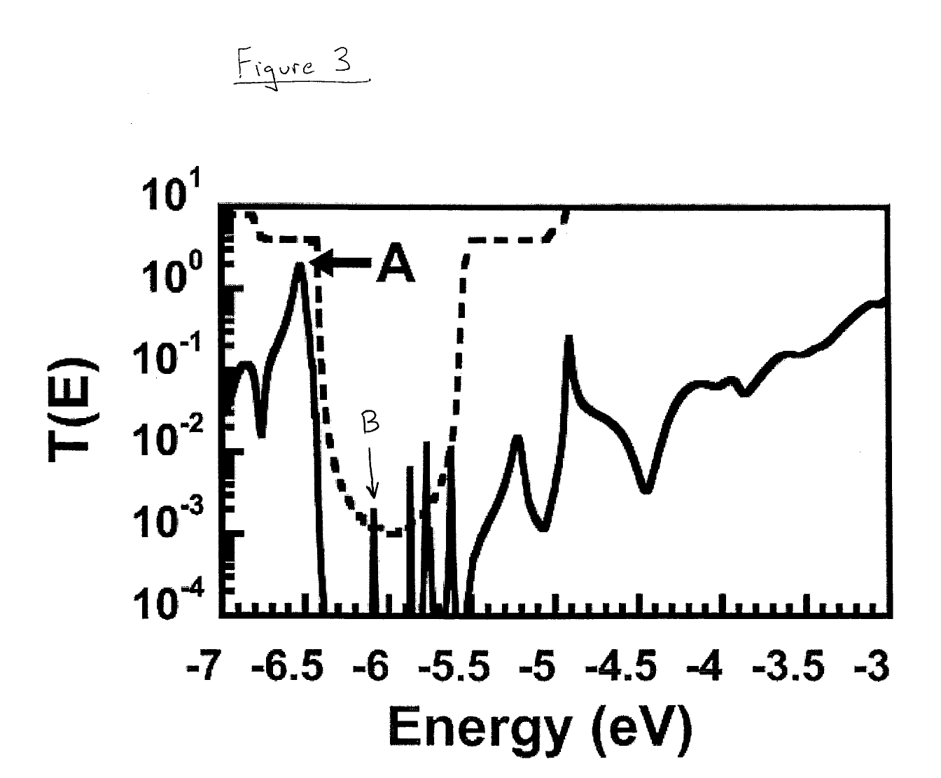

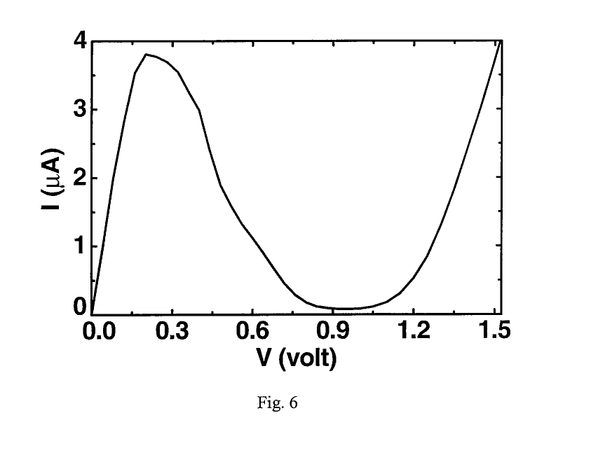

The RTD device of FIG. 2 was modeled for quantum electron transport using density functional theory in conjunction with non-equilibrium Green function formulism. Modeling results indicate that the structure shown in FIG. 2 exhibits good hole transport as a p-type RTD device where resonance states in the valance band are confined within the molecular pseudopeptide 13. The structure was optimized using the MMX force-field method built into the PCMODEL software version 9.00.0 (available from Serena Software). For comparison, FIG. 3 shows a plot of the CNT 11-pseudopeptide 13-CNT 12 (CNT-P-CNT) transmission (solid line) overlaid on a plot of a bare (10,0) zigzag CNT transmission (dashed line). The band-gap begins at −6.5 eV and ends close to −5.5 eV. The peak transmission at approximately −6.53 eV (point A) indicates good hole transfer through the device. A resonant state (point A) near a band edge is the essence of a resonant tunnel diode (RTD). The calculated current voltage (I-V) response of this structure is shown in FIG. 6. It displays negative differential resistance and the classic shape of an RTD I-V curve.

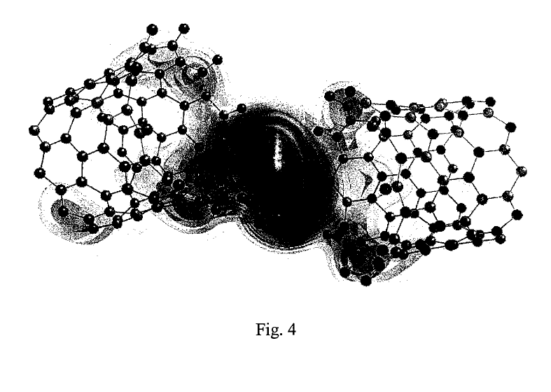

The resonant state at point A was examined with a surface contour plot seen in FIG. 4 which corresponds to the spectral function at point A. The electron cloud of the CNT valence bands can be seen around the CNT leads, indicating electron transport between the two semiconducting CNTs 11,12. The results demonstrate that the semiconducting leads 11,12 combined with a functional biological component 13 behaves as a molecular RTD device.

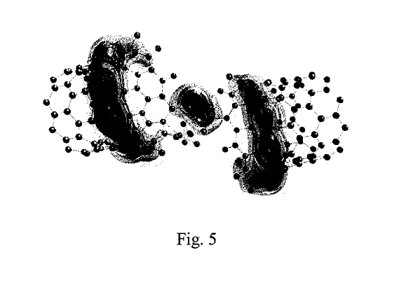

FIG. 5 illustrates a surface contour plot corresponding to the spectral function at point B of FIG. 3. The state is confined to the pseudopeptide and exposed surface of the CNTs. There is no electron cloud further back in the CNT leads since the energy lies within the bandgap of the CNTs. The transmission within the energies of the CNT bandgap is the result of resonant tunneling from the CNT end through the interface/peptide states out to the other CNT end. It should be appreciated that the transmission in the bandgap is exponentially dependent on the CNT length. i.e., T(E) ≈e^{-2kL}_{CNT}, where k represents the evanescent wavevector in the bandgap of the CNTs. As the CNT lengths are increased, the resonant tunneling current observed in the bandgap will be exponentially suppressed.

### REFERENCES

The following references, cited above, are each hereby incorporated by reference in their entirety.

[1] E. Katz and I. Willner, “Integrated nanoparticle-biomolecule hybrid systems: Synthesis, properties, and applications,” Angew. Chem. Int. Ed., vol. 43, pp. 6042-6108, 2004.

[2] E. Katz and I. Willner, “Biomolecule-functionalized carbon nanotubes: Applications in nanobioelectronics,” ChemPhysChem, vol. 5, pp. 1085-1104, 2004.

[3] W. Fritzsche, Ed., DNA-Based Molecular Electronics. New York: AIP, 2004, vol. 725.

[4] C. A. Mirkin, R. L. Letsinger, R. C. Mucic, and J. J. Storhoff, “A dna-based method for rationally assembling nanoparticles into macroscopic materials,” Nature, vol. 382, pp. 607-609, 1996.

[5] A. P. Alivisatos, K. P. Johnsson, X. G. Peng, T. E. Wilson, C. J. Loweth, M. P. Bruchez, and P. G. Schultz, “Organization of nanocrystal molecules using dna,” Nature, vol. 382, pp. 609-611, 1996.

[6] K. Keren, R. S. Berman, E. Buchstab, U. Sivan, and E. Braun, “Dna-templated carbon nanotube field-effect transistor,” Science, vol. 302, pp. 1380-1382, 2003.

[7] S. Heinze, J. Tersoff, R. Martel, V. Derycke, J. Appenzeller, and P. Avouris, “Carbon nanotubes as Schottky barrier transistors,” Phys. Rev. Lett., vol. 89, no. 10, p. 106801, 2002.

[8] M. Radosavljevic, S. Heinze, J. Tersoff, and P. Avouris, “Drain voltage scaling in carbon nanotube transistors,” Appl. Phys. Lett., vol. 83, no. 12, pp. 2435-2437, 2003.

[9] S. J. Wind, J. Appenzeller, R. Martel, V. Derycke, and P. Avouris, “Vertical scaling of carbon nanotube field-effect transistors using top gate electrodes,” Appl. Phys. Lett., vol. 80, pp. 3817-3819, 2002.

[10] R. Martel, V. Derycke, C. Lavoie, J. Appenzeller, K. K. Chan, J. Terso, and P. Avouris, “Ambipolar electrical transport in semiconducting single wall carbon nanotubes,” Phys. Rev. Lett., vol. 87, no. 25, p. 256805, 2001.

[11] R. M. Stoltenberg and A. T. Woolley, “Dna-templated nanowire fabrication,” Biomedical Microdevices, vol. 6, no. 2, pp. 105-111, 2004.

[12] A. Javey, J. Guo, Q. Wang, M. Lundstrom, and H. Dai, “Ballistic carbon nanotube field-effect transistors,” Nature, vol. 424, pp. 654-657, 2003.

[13] A. Javey, J. Guo, M. Paulsson, Q. Wang, D. Mann, M. Lundstrom, and H. Dai, “High-field quasiballistic transport in short carbon nanotubes,” Phys. Rev. Lett., vol. 92, no. 10, p. 106804, 2004.

[14] A. Javey, J. Guo, D. B. Farmer, Q. Wang, D. Wang, R. G. Gordon, M. Lundstrom, and H. Dai, “Carbon nanotube field-effect transistors with integrated ohmic contacts and high-K gate dielectrics,” Nano Lett., vol. 4, no. 3, pp. 447-450, 2004.

[15] A. Javey, J. Guo, D. B. Farmer, Q. Wang, E. Yenilmez, R. G. Gordon, M. Lundstrom, and H. Dai, “Self-aligned ballistic molecular transistors and electrically parallel nanotube arrays,” Nano Lett., vol. 4, no. 7, pp. 1319-1322, 2004.

[16] T. Rakshit, G. Liang, A. Ghosh, and S. Datta, “Silicon-based molecular electronics,” Nano Lett., vol. 4, p. 1083, 2004.

[17] P. Damle, A. Ghosh, and S. Datta, “Unified description of molecular conduction: From molecules to metallic wires,” Phys. Rev. B, vol. 64, p. 201403, 2001.

[18] P. Damle, A. Ghosh, and S. Datta, “First-principles analysis of molecular conduction using quantum chemistry software,” Chem. Phys., vol. 281, no. 2-3, pp. 171-188, 2002.

[19] Y. Xue, S. Datta, and M. A. Ratner, “First-principles based matrix green's function approach to molecular electronic devices: general formalism,” Chem. Phys., vol. 281, no. 2-3, pp. 151-170, 2002.

[20] Y. Xue, S. Datta, and M. A. Ratner, Charge transfer and band lineup in molecular electronic devices: A chemical and numerical interpretation,” J. Chem. Phys., vol. 115, no. 9, pp. 4292-4299, 2001.

[21] S. N. Yaliraki and M. A. Ratner, “Molecule-interface coupling effects on electronic transport in molecular wires,” J. Chem. Phys., vol. 109, no. 12, pp. 5036-5043, 1998.

[22] M. A. Reed, J. Chen, A. M. Rawlett, D. W. Price, and J. M. Tour, “Molecular random access memory cell,” Appl. Phys. Lett., vol. 78, no. 23, pp. 3735-3737, 2001.

[23] J. Chen and M. A. Reed, “Electronic transport of molecular systems,” Chem. Phys., vol. 281, no. 2-3, pp. 127-145, 2002.

[24] R. Lake, “Full quantum simulation, design, and analysis of si tunnel diodes, mos leakage and capacitance, hemts, and rtds,” in 2001 IEDM Technical Digest. New York: IEEE, 2001, pp. 5.5.1-5.5.4.

[25] J. P. A. van der Wagt, A. C. Seabaugh, and E. Beam III, “RTD/HFET low standby power sram gain cell,” IEEE EDL, vol. 19, p. 7, 1998.

[26] R. R. Pandey, N. Bruque, K. A. Alam, and R. K. Lake, ‘Carbon nanotube—molecular resonant tunneling diode,’ Phys. Stat. Sol. (a), vol. 203, p. R5, 2006.

[27] N. Bruque, R. R. Pandey, and R. K. Lake, ‘Electronic Transport Through a CNT-Pseudopeptide-CNT Hybrid Material,’ Molecular Simulation, vol. 31, p. 859, 2005.

While the invention has been described by way of example and in terms of the specific embodiments, it is to be understood that the invention is not limited to the disclosed embodiments. To the contrary, it is intended to cover various modifications and similar arrangements as would be apparent to those skilled in the art. Therefore, the scope of the appended claims should be accorded the broadest interpretation so as to encompass all such modifications and similar arrangements.

What is claimed is:

1. A molecular resonant tunneling diode (RTD), comprising:
a first semiconducting carbon nanotube (CNT) lead;
a second CNT lead; and
organic material coupling the first and second CNT leads wherein the organic material is chemically bonded to a proximal end of the first CNT lead and to a proximal end of the second CNT lead.

2. The RTD of claim 1, wherein the second CNT lead is an (n, m) CNT where (n−m)/3 is not an integer.

3. The RTD of claim 2, wherein n=10 and m=0.

4. The RTD of claim 2, wherein the organic material comprises a pseudopeptide molecule.

5. The RTD of claim 1, wherein the organic material comprises a material selected from the group consisting of disubstituted oligomeric olefines, disubstituted oligomeric alkanes, polyaromatics, 2,5-disubstituted oligothiophenes and dimercaptodiphenylacetylene.

6. The RTD of claim 1, wherein the proximal ends of the first CNT and second CNT leads are passivated.

7. The RTD of claim 1, wherein the proximal ends of the first CNT and second CNT leads are passivated with hydrogen atoms.

8. The RTD of claim 1, wherein the proximal ends of the first and second CNT leads are not metallized.

9. The RTD of claim 1, wherein the organic material comprises a material selected from one of the ester group (—COO—), the thioester group (—COS—) and the imino group (—HC═N—).

10. The RTD of claim 1, wherein the first and second CNT leads are (n, m) CNTs, where (n−m)/3 is not an integer.

11. The RTD of claim 10, wherein n=10 and m=0 for both the first and second CNTs.

12. The RTD of claim 1, wherein the second CNT lead is semiconducting.

13. The RTD of claim 1, wherein the second CNT lead is metallic.
